(19) United States
(12) Patent Application Publication
(10) Pub. No.: US 2018/0158926 A1
(43) Pub. Date: Jun. 7, 2018

(54) PROCESS OF FORMING SEMICONDUCTOR DEVICE

(71) Applicant: SUMITOMO ELECTRIC INDUSTRIES, LTD., Osaka (JP)

(72) Inventors: Ken Nakata, Yokohama-shi (JP); Isao Makabe, Yokohama-shi (JP)

(73) Assignee: SUMITOMO ELECTRIC INDUSTRIES, LTD., Osaka (JP)

(21) Appl. No.: 15/830,582

(22) Filed: Dec. 4, 2017

(30) Foreign Application Priority Data
Dec. 5, 2016 (JP) 2016-235755

(51) Int. Cl. H01L 29/66; H01L 29/20; H01L 29/205; H01L 29/778; H01L 21/02; C30B 25/16; C30B 29/40

(52) U.S. Cl. CPC H01L 29/66462; H01L 29/2003; H01L 29/205; H01L 29/7787; H01L 21/02378; C30B 29/403; H01L 21/0254; H01L 21/0262; C30B 25/16; C30B 29/406; H01L 21/02458

(57) ABSTRACT

A process of forming a nitride semiconductor is disclosed. The process includes steps of (a) growing an aluminum gallium nitride (GaN) as a channel layer, and (b) growing an indium aluminum gallium nitride (InAlGaN) as a barrier layer. The InAlGaN layer is grown at a temperature lower than a growth temperature for the GaN, and has an indium (In) composition less than 14% but preferably greater than 10%. The InAlGaN is substantially lattice-matched with the GaN.

### CROSS REFERENCE TO RELATED APPLICATION

The present application claims the benefit of priority of Japanese Patent Application No. 2016-235755, filed on Dec. 5, 2016, which is incorporated herein by reference.

### BACKGROUND OF INVENTION

### 1. Field of the Invention

The present invention relates to a process of forming a semiconductor device primarily made of nitride semiconductor materials.

### 2. Background Arts

A Japanese Patent application laid open No. JP-2008-118044A has disclosed a field effect transistor (FET) that includes a substrate, a gallium nitride (GaN) layer on the substrate, a barrier layer on the GaN layer, where the barrier layer is made of one of aluminum gallium nitride (AlGaN), indium aluminum nitride (InAlN), and indium aluminum gallium nitride (InAlGaN), a silicon carbide (SiC) layer on the barrier layer, and electrodes of a source, a drain, and a gate on the barrier layer.

One type of the FET called as high electron-mobility transistor (HEMT) inherently shows excellent high frequency performance. In particular, a HEMT made of nitride semiconductor materials may make a high speed operation consistent with a high breakdown voltage. A HEMT generally provides a channel layer and a barrier layer for inducing a two-dimensional electron gas (2DEG) in an interface between the channel layer and the barrier layer. A nitride HEMT conventionally provides the AlGaN barrier layer and the GaN channel layer. In order to enhance the high frequency performance of a HEMT, an enhanced trans-conductance becomes substantial and a thinner barrier layer may effectively contribute the increase of the trans-conductance. However, a thinned AlGaN barrier layer in a conventional HEMT to enhance the trans-conductance generally accompanies with a reduction of a carrier concentration in the 2DEG, which resultantly makes the trans-conductance hard to be enhanced. A thinned InAlN barrier layer has an advantage of suppressing the reduction of the carrier concentration in the 2DEG.

However, an InAlN barrier layer possibly increases the gate leak current (Ig) compared with the AlGaN barrier layer. The InAlN barrier layer may strengthen an internal electric field because of the increase of the carrier concentration in the 2DEG. Besides, because an InAlN layer inherently has poorer quality compared with an AlGaN layer, the leak current through defects caused by surface pits and/or impurity levels derived from dislocations and so on within a crystal may possibly increase. Various techniques have been reported in the field, such as a cap layer made of GaN covering the InAlN barrier layer or an insulating film continuously deposited on the InAlN barrier layer within a growth reactor without exposing a surface of the InAlN layer to atmosphere to form a metal-insulator-metal (MIS) structure. However, those know techniques, although effectively reduces the gate leak current, have inevitably decreased the carrier concentration in the 2DEG.

### SUMMARY

An aspect of the present invention relates to a process of forming a nitride semiconductor device that includes steps of: (a) epitaxially growing a channel layer, and (b) epitaxially growing an indium aluminum gallium nitride (InAlGaN) as a barrier layer on the channel layer. The channel layer may be made of gallium nitride (GaN) to form a two-dimensional electron gas (2DEG) in an interface between the GaN layer and the InAlGaN layer. A feature of the process according to the aspect of the present invention is that the InAlGaN grown on the GaN has indium (In) composition of 14% at most and preferably at least 10%.

The step (b) of growing the InAlGaN may be carried out under a growth pressure of 40 to 70 Torr, and the grown InAlGaN may be substantially lattice-matched with the GaN channel layer.

The process may further include a step of, after the growth of the InAlGaN layer, growing another GaN layer on the InAlGaN layer by a thickness of about 3 nm, where the InAlGaN layer beneath the another GaN layer is grown by a thickness of about 9 nm.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 schematically shows a cross section of an epitaxial wafer for a semiconductor device according to embodiment of the present invention;

FIG. 2 shows a cross section of the semiconductor device according to the embodiment of the present invention;

FIG. 3 is a flow chart of a process of forming the semiconductor device shown in FIG. 2;

FIG. 4 shows a relation of bandgap energy against a lattice constant of nitride semiconductor materials;

FIG. 5 shows an example of variation in a growth temperature for sequentially growing a GaN channel layer, an InAlN barrier layer, and a GaN cap layer (or an insulating film);

FIG. 6 shows a variation of carrier concentration in a two-dimensional electron gas (2DEG) for various indium compositions of InAlGaN barrier layer before and after a heat treatment;

FIG. 7 shows a relation of stability in a composition of InAlGaN layer against a growth pressure; and

FIG. 8 shows a relation of a gate leak current against a carrier concentration in the 2DEG for various indium compositions of InAlGaN.

### DETAILED DESCRIPTION

Next, embodiment according to the present invention will be described as referring to accompanying drawings. It will, however, be evident that various modifications and changes may be made thereto without departing from broader spirit and scope of the present invention. The present specification and figures are accordingly to be regarded as illustrative rather than restrictive. Also, in the description of the drawings, numerals or symbols same with or similar to each other will refer to elements same with or similar to each other without presenting duplicated explanations.

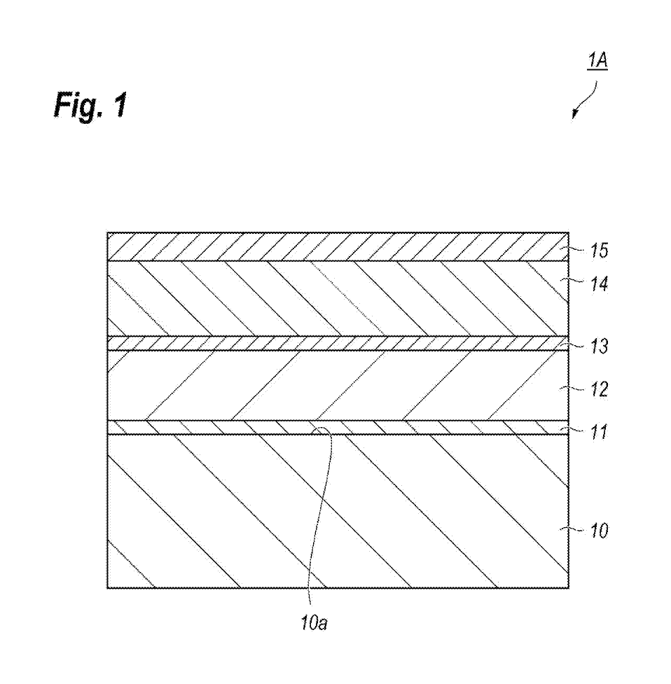

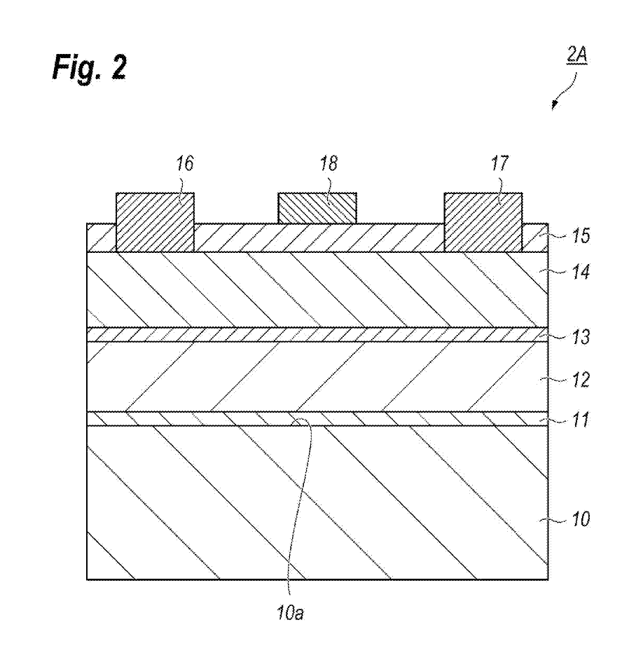

FIG. 1 shows a cross section of an epitaxial substrate 1A subject to a semiconductor device 2A of the present embodiment, and FIG. 2 shows a cross section of a semiconductor device 2A type of high electron-mobility transistor (HEMT) according to embodiment of the present embodiment. The epitaxial substrate 1A shown in FIG. 1, which may be made of nitride semiconductor materials, includes a substrate 10 made of silicon carbide (SiC) 10, a buffer layer 11 made of aluminum nitride (AlN), a channel layer 12 made of gallium nitride (GaN), a spacer layer 13 made of aluminum nitride (AlN), a barrier layer 14 made of indium aluminum gallium nitride (InAlGaN), and a cap layer 15 made of gallium nitride (GaN), where the respective layers, 11 to 15, are stacked on the substrate 10 in this order. The HEMT 2A shown in FIG. 2 may be formed based on the epitaxial substrate 1A shown in FIG. 1; that is, the HEMT 2A provides electrodes of a source 16, a drain 17, and a gate 18 on the epitaxial substrate 1A.

The SiC substrate 10 has a semi-insulating characteristic. The AlN layer 11, which is epitaxially grown on a primary surface 10a of the SiC substrate 10 with a thickness of 10 to 30 nm, operates as a buffer layer and a seed layer for growing the GaN layer 12 thereon. The AlN layer 11 of the present embodiment has a thickness of 20 nm. The GaN layer 12 operates as a channel layer, or a carrier transporting layer. Because a GaN layer is hard or substantially unable to grown directly on a SiC substrate due to wettability of a GaN material against a SiC material; the AlN layer 11 is interposed between the SiC substrate 10 and the GaN channel layer 12. Accordingly, the AlN buffer layer 11 is sometimes called as a nucleus forming layer. The GaN channel layer 12 may have a thickness greater than 400 nm but smaller than 1000 nm. The GaN channel layer 12 of the embodiment has a thickness of 500 nm. The AlN layer 13, which is interposed between the GaN channel layer 12 and the InAlGaN barrier layer 14, is operable as a spacer layer that suppresses the alloy-disorder scattering for carriers in a two dimensional electron gas (2DEG) formed in the interface between the GaN channel layer 12 and the AlN spacer layer 13, where the alloy-disordered scattering is caused by disordered dispositions of group III materials in the InAlGaN barrier layer 14. The AlN spacer layer 13 preferably has a thickness of 0.5 to 1.0 nm, where the HEMT 2A of the embodiment provides the AlN spacer layer 13 with a thickness of 1 nm.

The InAlGaN layer 14, which is epitaxially grown on the AlN spacer layer 13, operates as a barrier layer, or in other words, a carrier-supplying layer. Conventionally, a channel layer and a barrier layer induce piezoelectricity due to a difference in respective lattice constants; that is, the difference in the lattice constants causes distortion in respective crystals in portions neighbor to the interface therebetween, and this mechanical distortion may induce the piezoelectricity in the channel layer because the channel layer has bandgap energy smaller than that of the barrier layer. Although the present embodiment provides the spacer layer 13 made of AlN, the piezoelectricity is induced in the GaN channel layer 12 because the AlN spacer layer 13 is thin enough not to compensate the difference in the lattice constant between the GaN channel layer 12 and the InAlGaN barrier layer 14. The InAlGaN barrier layer 14 has the indium (In) composition at least 10% but at most 14%.

Contrary to the conventional barrier layer described above, the InAlGaN layer 14 of the present embodiment has a lattice constant substantially matching with that of the GaN layer 12. Accordingly, contribution to the carriers in the 2DEG from the piezoelectricity is limited. The carriers are induced in the 2DEG primarily by the polarization charges of the InAlGaN layer 14. The InAlGaN layer 14 is lattice-matched with the GaN layer 12. The compositions of group III elements in the InAlGaN layer 14 may be determined such that the InAlGaN layer 14 matches the lattice constant thereof with that of the GaN layer 12. The lattice matching means that the difference in the lattice constants is within ±1% with respect to the lattice constant of the GaN layer 12. The InAlGaN layer 14 has a thickness of at least 5 nm but at most 15 nm. The present embodiment has the InAlGaN layer 14 with a thickness of 9 nm.

The other GaN layer 15, which is epitaxially grown on the InAlGaN layer 14, operates as a cap layer to suppress dissolution of indium (In) atoms from the InAlGaN layer 14 and oxidization of aluminum (Al) in the InAlGaN layer 14. The GaN layer 15 may have a thickness of at least 1 nm but at most 5 nm, where the present embodiment has the thickness of 3 nm.

The source electrode 16 and the drain electrode 17, which are provided on the InAlGaN layer 14, show non-rectified contact against the InAlGaN layer 14. Those electrodes, 16 and 17, may be formed by alloying a stacked metal of titanium (Ti) and aluminum (Al) at a temperature above 500° C. The gate electrode 18 is provided also on the InAlGaN layer 14 and between the source electrode 16 and the drain electrode 17. The gate electrode 18 may have a stacked metal of nickel (Ni) and gold (Au), where the Ni layer is in contact with the InAlGaN layer 14.

Although the embodiment of the present invention above described provides the GaN cap layer 15 on the InAlGaN layer 14, the embodiment may further provide an insulating film on the GaN layer 15, or, in an alternative, the embodiment may remove the GaN layer 15, where the InAlGaN layer 14 is directly covered with the insulating film. Such arrangements providing the insulating film may form a HEMT 2A with a metal-insulator-semiconductor (MIS) structure.

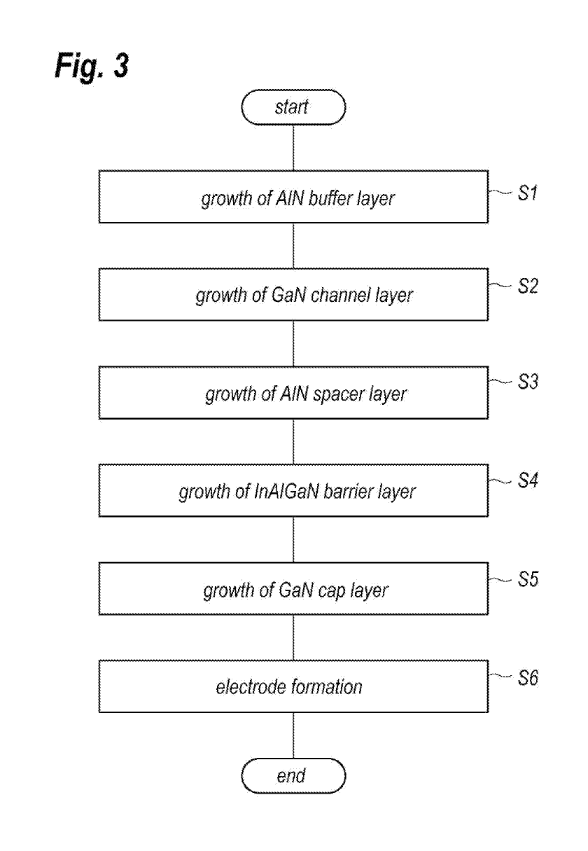

Next, the process of forming the epitaxial substrate 1A and the semiconductor device 2A will be described as referring to a flow chart shown in FIG. 3. The process first grows the AlN layer 11 on the SiC substrate 10 by the metal organic chemical vapor deposition (MOCVD) technique at step S1. The epitaxial growth uses tri-methyl-aluminum (TMA) as a source material for a group III element, namely aluminum (Al), and ammonia (NH₃) as a source material for a group V element, namely nitrogen (N). Also, the epitaxial growth is done at a temperature exceeding 1000° C., where the embodiment carries out the growth at 1100° C. Temperatures defined below mean those within a growth chamber of the MOCVD apparatus, specifically, those of a susceptor on which the substrate 10 is placed.

Thereafter, the process grows the GaN layer 12 on the AlN layer 11 at step S2. The embodiment uses tri-methyl-gallium (TMG) as a source material for a group III element, namely gallium (Ga), and also ammonia (NH₃) for nitrogen (N). The growth temperature exceeds 1000° C. and the embodiment sets the growth temperature to be 1050° C.

Thereafter, the process grows the AlN layer 13 at step S3 using TMA and ammonia (NH₃), which are same with those for the aforementioned AlN layer 11, but the growth temperature for the AlN layer 13 is lower than the growth temperature for the GaN layer 12. Specifically, the embodiment sets the growth temperature for the AlN layer 13 to be higher than 600° C. but lower than 800° C., typically 700° C., and a growth pressure higher than 40 Torr but lower than 70 Torr, typically 50 Torr, where one (1) Torr corresponds to 133.322 Pascal (Pa).

Thereafter, the process grows the InAlGaN layer 14 on the AlN layer 13 at step S4 using tri-methyl-indium (TMI), TMA, TMG, and ammonia (NH₃) for indium (In), Al, Ga, and N, respectively. The grown InAlGaN layer 14 has the indium composition at least 10% but at most 14%.

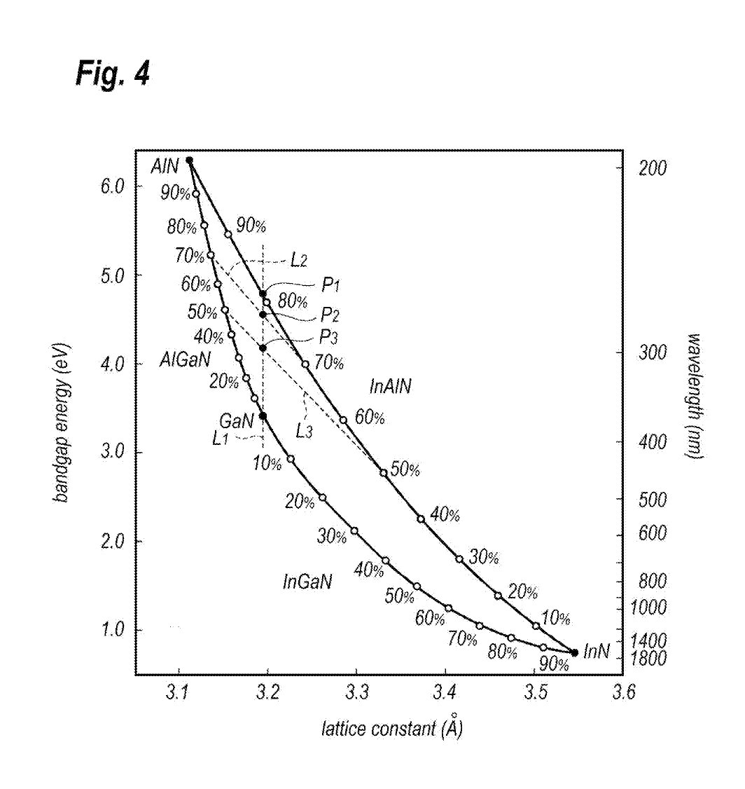

FIG. 4 shows a diagram of the bandgap energy, equivalently the bandgap wavelength, against the lattice constant in InₓAl_{y}Ga_{1-x-y}N quaternary compound material, where the horizontal axis denotes the lattice constant in a unit of angstrom, while, the vertical axis denotes the bandgap energy in a unit of electron-volt (eV), or reverse of the bandgap wavelength in a unit of nano-meter (nm). A broken line L₁ corresponds to materials whose lattice constant matches with that of GaN, a broken line L₂ corresponds to materials whose aluminum composition is 70%, that is, materials of InₓAl_{0.7}Ga_{1-x-0.7}N, and a broken line L₃ corresponds to materials whose Al composition is 50%, that is, materials of InₓAl_{0.5}Ga_{1-x-0.5}N, respectively. The InAlGaN layer 14 of the present embodiment provides compositions of group III elements on the broken line L₁, that is, the InAlGaN layer 14 has the composition on the broken line L₁, for instance, In_{0.14}Al_{0.70}Ga_{0.16}N at the point P₂, In_{0.1}Al_{0.5}Ga_{0.4}N at point P₃, and so on.

The process at step S4 sets the growth temperature lower than those at steps S1 and S2. Specifically, the growth temperature for the InAlGaN layer 14 is preferably higher than 600° C. but lower than 800° C., further preferably to be around 700° C. The growth pressure at step S4 is preferably higher than 40 Torr but lower than 70 Torr, further preferably about 50 Torr.

Thereafter, the process grows the GaN layer 15 on the InAlGaN layer 14 at step S5 using TMG and NH₃ for the group III element (Ga) and the group V element (N), respectively at a growth temperature higher than 800° C. but lower than 900° C., preferably about 850° C., which is far lower than the growth temperature for the GaN layer 12, but higher than the growth temperature for the InAlGaN layer 14. The former condition, namely, lower than that for the GaN layer 12, is due to the existence of the InAlGaN layer 14. An excess growth temperature may cause the dissolution of indium atoms from the InAlGaN layer 14. On the other hand, the latter condition, namely, higher than that for the InAlGaN layer 14, is requested from the crystal quality of the grown GaN layer 15. Thus, the process of forming the epitaxial substrate 1A is completed.

When the semiconductor device is formed, the process may further proceed steps of etching a portion of the GaN layer 15, forming the source electrode 16 and the drain electrode 17 such that the electrodes, 16 and 17, are in direct contact with the InAlGaN layer 14 through the partially etched GaN layer 15, and forming the gate electrode 18 onto the GaN layer 15 at step S6. Those processes of forming the electrodes, 16 to 18, may utilize a conventional photolithography, metal deposition, and subsequent metal lift-off technique.

When the insulating film is provided on, or substituted from the GaN layer 15, the process may form the insulating film, which may be made of silicon nitride (SiN), under a temperature higher than 800° C., or comparable to the growth temperature for the GaN layer 15. The insulating film may be formed in situ, that is, may be continuously formed subsequent to the growth of the semiconductor layers, 11 to 15, within the growth reactor without extracting the substrate out of the growth reactor. This in situ process may suppress the oxidization of the surface of the epitaxial substrate 1A, the adhesion of impurities onto the epitaxial substrate 1A, and so on. The semiconductor device 2A may increase the operational stability and the long-term reliability thereof.

Next, advantages of the process of forming the epitaxial substrate 1A and the semiconductor device 2A will be described.

Electron devices primarily formed by nitride semiconductor materials such as gallium nitride (GaN) have become popular in the field. In particular, a field effect transistor type of high electron-mobility transistor (HEMT) may make a high-speed operation consistent with a high breakdown voltage by using nitride semiconductor materials. In addition, a semiconductor device with a high electron concentration and operable in a high frequency region has been developed. Such a nitride semiconductor device often provides a channel layer made of GaN and a barrier layer made of AlGaN, where a two-dimensional electron gas (2DEG) is induced in an interface between the GaN channel layer and AlGaN barrier layer.

Also, a HEMT providing a barrier layer made of InAlN instead of the AlGaN barrier layer has been known in the field. It is also well known that, in order to improve high frequency performances of a semiconductor device, enhancement of the trans-conductance (gin) becomes effective. However, as to the barrier layer made of AlGaN, a thinned AlGaN layer could be effective for increasing the trans-conductance, but such a thinned layer inevitably reduces the carrier concentration in the 2DEG, which resultantly makes hard to increase the trans-conductance. On the other hand, the barrier layer made of InAlN may suppress the reduction of the carrier concentration in the 2DEG even when the InAlN layer is thinned.

One of subjects left in the InAlN barrier layer is that, when an FET provides an InAlN barrier layer, the gate leak current Ig becomes larger compared with the AlGaN barrier layer. This is because an InAlN may increase the carrier concentration in the 2DEG, which inevitably strengthens the internal electric field and lesser crystal quality of InAlN itself. Dislocations within an InAlN crystal and defects appearing in the surface thereof are easily converted into various levels within the energy gap of InAlN material and leak currents interposing those levels increase. Various technique have been reposted to reduce the gate leak current, for instance, an InAlN barrier layer is covered with a cap layer, and/or, an insulating film such as silicon nitride (SiN) is deposited onto the InAlN barrier without exposing the surface of the InAlN barrier layer to air, that is, the FET type of metal-insulator-semiconductor (MIS) is formed. However, those techniques already reported are unsatisfying in a viewpoint of the carrier concentration. That is, the techniques already reported, although they reduce the gate leak current, accompany with the reduction of the carrier concentration in the 2DEG which is a most favorable feature of the InAlN barrier layer.

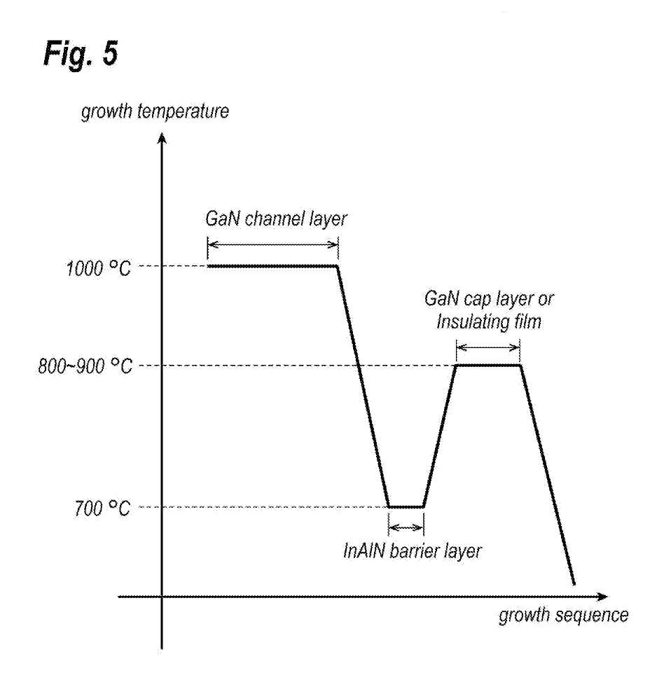

One possible reason of reduction of the carrier concentration in the 2DEG is seemed to be a higher growth temperature for the GaN cap layer, and/or, a higher depositing temperature for the insulating film. The InAlN barrier layer is ordinarily grown at a temperature lower than 700° C. to increase the indium (In) composition. On the other hand, the growth of the GaN cap layer, or the deposition of the insulating film, is inevitably carried out under a temperature higher than 800° C. FIG. 5 schematically explains the sequence of growing the semiconductor layers. The GaN channel layer is often grown at a temperature of 1000° C. or higher; then, the InAlN barrier layer is grown after lowering the temperature down to 700° C.; finally, the temperature is raised again to 800 to 900° C. and the GaN cap layer is grown thereafter, which means that the InAlN barrier layer is exposed in a temperature higher than 800° C. Thus, the InAlN barrier layer in crystal quality thereof is forced to be degraded and the carrier concentration in the 2DEG is decreased. Growing the GaN cap layer at a relatively lower temperature, for instance around 700° C., or depositing the insulating film at a lower temperature; the GaN cap layer, or the insulating film, degrades the quality thereof and the reduction of the current collapse becomes hard.

The InAlN barrier layer, exactly, In_{0.18}Al_{0.82}N, has a higher aluminum (Al) composition (82%) compared with that of AlGaN with Al composition of 20 to 30%, which inevitably induces higher polarization charges. Besides, the InAlN has bandgap energy higher than that of the AlGaN. Those characteristics may be also attributed to InAlGaN that adds gallium (Ga) with InAlN by adjusting compositions of indium (In) and aluminum (Al). Specifically, an FET having an InAlGaN barrier layer that has the bandgap energy comparable to that of InAlN, further specifically, the bandgap energy greater than 4.0 eV, may show high frequency performances unable to the conventional AlGaN barrier layer.

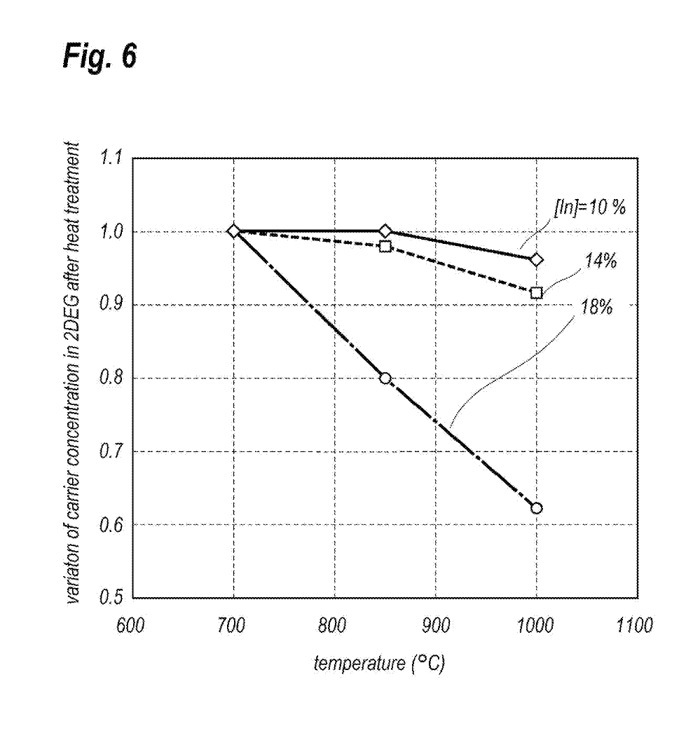

Because not only InAlN but InAlGaN contains indium (In) and indium (In) inherently has lesser tolerance against heat, those materials are possibly degraded in the crystal quality thereof by heat treatment. FIG. 6 compares the reduction of the carrier concentration in the 2DEG after the heat treatment in various InAlGaN materials having indium compositions [In] of 10, 14, and 18%, where the indium composition of 18% corresponds to the conventional In_{0.18}Al_{0.82}N, which is indicated by the point P₁ in FIG. 4. The indium compositions of 14% and 10% correspond to the points P₂ and P₃, respectively, each also indicated in FIG. 4. In FIG. 6, the vertical axis is normalized at the carrier concentrations before the heat treatment. As shown in FIG. 6, the InAlN with the indium composition of 18% explicitly reduces the carrier concentration in the 2DEG by the heat treatment even at the heat treatment of 850° C., but the InAlGaN with the aluminum compositions of 14% and 10% show smaller reduction of the carrier concentration. Especially, the indium composition of 10% for the InAlGaN shows substantially no reduction of the carrier concentration even after the heat treatment at 850° C.

Group III elements appear in the surface of InAlGaN crystal, and six elements are disposed around one element because InAlGaN crystal has the crystal structure type of hexagonal close packed (hcp). That is, an InAlGaN crystal having indium composition greater than 16.7%, an In-In bond may exist, or increases the possibility of existence thereof in the surface. In a case the indium composition of 16.7% or smaller, the possibility that the In—In bond appears in the surface becomes smaller. Accordingly, the reason why the reduction of the carrier concentration in the 2DEG shown in FIG. 6 causes a large difference between the indium composition of 18% and that of 14% seems to be the existence of the In—In bond in the surface. Besides, the indium composition at least 10% in InAlGaN in the barrier layer may show advantages compared with AlGaN, that is, even a thinner barrier layer to enhance the trans-conductance may suppress the reduction of the carrier concentration in the 2DEG.

A reason that an InAlGaN layer is conventionally not applied for the barrier layer is as follows: That is, InAlN and/or AlGaN is a ternary compound, while, InAlGaN is a quaternary compound, which makes drastically hard to grow the layer epitaxially. In particular, a quaternary compound with respective compositions of elements greater than 10%, for instance, In_{0.14}Ga_{0.16}Al_{0.70}N corresponding to point P₂, the conventional epitaxial growth becomes almost impossible in a viewpoint of the reproducibility.

Nitride semiconductor materials are generally grown under a growth pressure of 150 to 300 Torr, but InAlGaN layer of the embodiment is grown under a growth pressure lower than 70 Torr, which is almost half or smaller than the conventional growth pressure. A lower growth pressure may suppress excess gas phase reaction and stabilize the compositions of the grown layer with good reproducibility. Specifically, a lower growth pressure may suppress reaction between atoms in a gas phase and stabilize the composition because atoms flow within a reactor with high speed. On the other hand, a lower pressure may enhance damages by hydrogens (H) introduced as a carrier gas and sublimations of constituent elements from a surface of a grown layer. However, an InAlGaN layer is grown at a relatively lower temperature and an extremely lower partial pressure of hydrogen (H) in the carrier gas, accordingly, the damage by the hydrogen (H) may be effectively suppressed, while, the stability of the compositions may be realized.

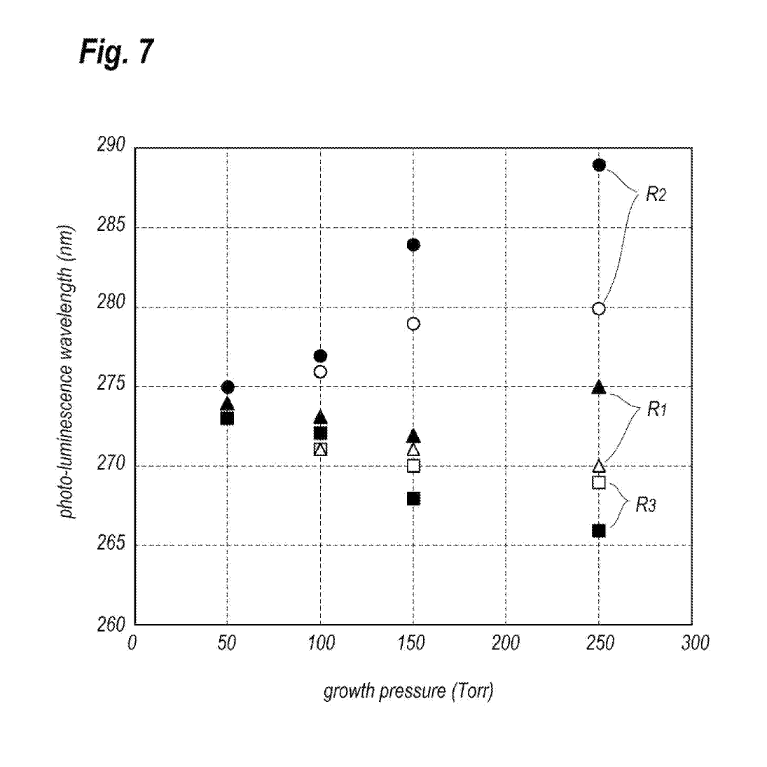

FIG. 7 shows a relation of the reproducibility of the composition against the growth pressure, where the horizontal axis corresponds to the growth pressure in the unit of Torr, while, the vertical axis shows peak wavelengths in photoluminescence spectra for grown InAlGaN layers. Symbols R₁ to R₃ correspond to positions, within a wafer with a diameter of 4 inches, each apart from a center by 40 mm, 0 mm, and −40 mm; and open symbols were results measured in one wafer, while, filed symbols were obtained from another wafer. The peak wavelengths of the photoluminescence spectra varied as the growth pressure increases, which means that the stability, or the reproducibility, of the composition in InAlGaN layer degraded. Also, the composition of InAlGaN layer stabilized when the growth pressure was lower than 70 Torr.

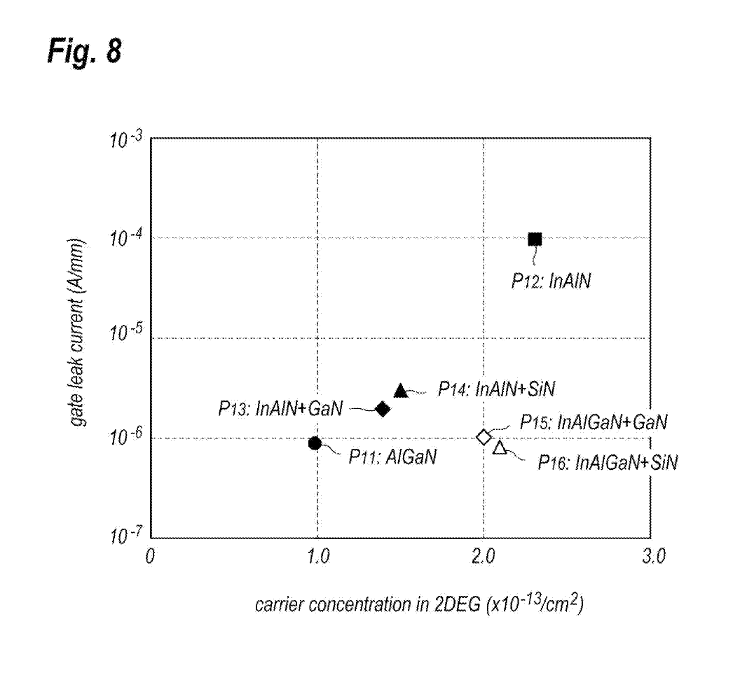

FIG. 8 compares the relation between the carrier concentration in the 2DEG and the gate leak current for various arrangements of the barrier layer and the cap layer, where the horizontal axis shows the carrier concentration in the 2DEG, while, the vertical axis shows the gate leak current of HEMTs having arrangements shown in FIG. 8. In FIG. 8, point P₁₁ corresponds to a conventional arrangement of the AlGaN barrier layer without any cap layers or insulating films thereon. Point P₁₂ corresponds to the InAlN barrier layer without the cap layer or the insulating film, that is, the conventional AlGaN barrier layer is only replaced to the InAlN barrier layer with the indium composition of 18%. The InAlGaN barrier layer was grown at temperature of 700° C. under a growth pressure of 50 Torr with a thickness of 9 nm. Points, P₁₃ and P₁₄, correspond to the arrangements that stack the GaN cap layer and the insulating film (SiN) on the InAlN barrier layer of the arrangement corresponding to point P₁₂, respectively. The arrangement of the InAlGaN barrier layer with the GaN cap layer were formed by conditions same with those for the InAlN barrier layer of point P₁₂ and subsequently under the conditions of a temperature of 850° C. for the GaN cap layer with a thickness of 3 nm. Points P₁₅ and P₁₆ correspond to the present embodiment, that is, the barrier layer is made of InAlGaN with the indium composition of 14% and stacks the GaN cap layer or the SiN film continuously formed within the growth reactor. In those experiments, the HEMTs had a gate width of 0.3 μm, a distance of 3.0 μm between the source electrode and the drain electrode, and the stacked gate metal of nickel (Ni) and gold (Au). The gate leak currents were measured by applying a bias of 50 V between the gate electrode and the drain electrode. The carrier concentration was measured by the Hall measurement.

Replacing the barrier layer from AlGaN to InAlN, the carrier concentration in the 2DEG increased twice or more, but accompanied with a drastic increase of the gate leak current. Continuously forming the GaN cap layer, or the SiN insulating film on the InAlN barrier layer, the gate leak current certainly decreased to a level comparable to that for the AlGaN barrier layer, but the carrier concentration also decreased to about a half of the original concentration without the cap layer or the insulating film. The present embodiment, that is, the barrier layer made of InAlGaN with the GAN cap layer or the SiN insulating film, may maintain the carrier concentration in a level substantially same with the arrangement of the InAlN barrier layer, besides, suppress the gate leak current in the level substantially same with the case of the AlGaN barrier layer. Thus, the invention may make the increase of the carrier concentration in the 2DEG consistent with the suppression of the increase of the gate leak current.

In FIG. 8, the InAlGaN barrier layer had a thickness of 9 nm, and the GaN cap layer and the SiN insulating film had a thickness of 3 nm, respectively, but both layers are not restricted to those thicknesses because the thicknesses of the InAlGaN barrier layer and the GaN cap layer, or the SiN insulating film, are insubstantial for the increase of the carrier concentration without increase of the gate leak current.

Also, the cap layer on the InAlGaN barrier layer is not restricted to GaN. A cap layer made of AlGaN layer may be applicable to the cap layer 15 in spite of a growth temperature for AlGaN comparable to a growth temperature for GaN. Also, the insulating film continuously formed within a growth reactor is not restricted to SiN. Other materials, such as silicon oxy-nitride (SiON), silicon oxide (SiO₂), aluminum oxide (Al₂O₃), aluminum oxy-nitride (AlON), and so on may be applicable as the insulating film, where those materials have greater bandgap energy to reduce the gate leak current effectively and able to be continuously grown within the growth reactor.

The InAlGaN barrier layer of the embodiment substantially lattice-matches with GaN, specifically, the InAlGaN barrier layer has a lattice constant within the surface thereof, exactly, a distance along the crystal axis “a”, with a difference against the lattice constant of that of GaN in a range less than 1%. Such a lattice-matched InAlGaN barrier layer may soften internal stress, which resultantly enhances the reliability of the HEMT. Even the InAlGaN barrier layer lattice-matches with the GaN channel layer may induce enough carries in the 2DEG.

Next, the process of forming the epitaxial substrate 1A and the HEMT 2A for the experiment shown in FIG. 8 will be described. An AlN buffer layer 11 was first grown on a semi-insulating substrate 10 made of SiC by the MOCVD technique using sources of the TMA for aluminum (Al) and ammonia (NH₃) for nitrogen, respectively, at a growth temperature of 1100° C. with a thickness of 20 nm. Thereafter, using also the MOCVD technique at the growth temperature of 1050° C., a channel layer 12 made of GaN is grown on the AlN layer 11 using sources of TMG for gallium (Ga) and ammonia (NH₃) for nitrogen (N) by a thickness of 500 nm. Thereafter, a spacer layer 13 made of aluminum nitride (AlN) is grown on the GaN channel layer 12 by a thickness of 1 nm by the MOCVD technique using sources of TMA for aluminum (Al) and ammonia (NH₃) for nitrogen (N) at a growth temperature of 700° C. and a growth pressure of 50 Torr. Thereafter, a barrier layer 14 made of InAlGaN is grown on the AlN spacer layer 13 by the MOCVD technique using sources of TMA, TMI, TMG, and ammonia (NH₃) for aluminum (Al), indium (In), gallium (Ga) and nitrogen (N), respectively, at a growth temperature of 700° C. and a growth pressure of 50 Torr. The InAlGaN barrier layer 14 has a thickness of 9 nm and the indium (In) composition of 14%. Then, after setting a growth temperature to be 850° C., a cap layer 15 made of gallium nitride (GaN) is grown on the InAlGaN barrier layer 14 by sources of TMG and ammonia (NH₃) for gallium (Ga) and nitrogen (N), respectively, by a thickness of 3 nm.

Thereafter, using a conventional lithography and a subsequent lift-off technique, ohmic metals of titanium (Ti) and aluminum (Al) are stacked on the InAlGaN barrier layer 14, and gate metals of nickel (Ni) and gold (Au) are stacked also on the InAlGaN barrier layer 14. Before the deposition of the gate metals, the stacked metals Ti/Al are alloyed at a temperature above 500° C. In the present embodiment, the temperature for alloying the ohmic metals is set to be 550° C. Covering the surface of the epitaxial substrate 1A and the electrodes of the source 16, the drain 17, and the gate 18 with an insulating film made of silicon nitride (SiN), a HEMT 2A according to the embodiment is completed.

The HEMT 2A thus formed has a gate length of 0.3 μm and a distance between the source electrode 16 and the drain electrode 17 of 3.0 μm. Applying a bias of 50 V between the gate electrode 18 and the drain electrode 17, the HEMT 2A, shows a gate leak current of 1 μA/mm (1×10⁻⁶ A/mm), and a Hall effect shows the carrier concentration of the two dimensional electron gas(2DEG) of 2.0×10¹³/cm², which corresponds to the point P₁₅ in FIG. 8.

In an alternative, depositing an insulating film made of SiN instead of the GaN cap layer using silane (SiH₄) and ammonia (NH₃), the HEMT shows the gate leak current of 0.8 μA/mm (8×10⁻⁷ A/mm) and the carrier concentration in the 2DEG of 2.1×10¹³/cm², which corresponds to the point P₁₆ in FIG. 8.

Another HEMT comparable to the HEMT of the present embodiment, where the comparable HEMT provides an InAlN barrier layer with a thickness of 9 nm and the indium composition of 18%, instead of InAlGaN barrier layer of the embodiment, that is also formed by the MOCVD technique using sources of TMA, TMI, and ammonia (NH₃) for aluminum (Al), indium (In), and nitrogen (N), respectively, at a growth temperature for 700° C. and a growth pressure of 50 Torr. Such a conventional HEMT shows the gate leak current of 100 μA/mm (10⁻⁴ A/mm), almost two scores greater than the leak current of the HEMT of the present embodiment, and the carrier concentration in the 2DEG of 2.3×10¹³/cm², which corresponds to the point P₁₂ in FIG. 8 and substantially comparable to the HEMT of the embodiment.

While particular embodiment of the present invention has been described herein for purposes of illustration, many modifications and changes will become apparent to those skilled in the art. Accordingly, the appended claims are intended to encompass all such modifications and changes as fall within the true spirit and scope of this invention.

What is claimed is:

1. A process of forming a nitride semiconductor device, comprising steps of:
epitaxially growing a channel layer made of gallium nitride (GaN) on a substrate; and
epitaxially growing an indium aluminum gallium nitride (InAlGaN) on the channel layer under a temperature lower than a temperature for growing the channel layer,
wherein the InAlGaN has indium (In) composition of 14% at most.

2. The process according to claim 1,
wherein the InAlGaN has the indium composition of 10% at least.

3. The process according to claim 1,
wherein the step of growing the GaN is carried out under the temperature higher than 1000° C., and the step of growing the InAlGaN is carried out under the temperature lower than 800° C.

4. The process according to claim 1,
wherein the step of growing the InAlGaN is carried out under a growth pressure of 40 to 70 Torr.

5. The process according to claim 1,
further including a step of growing another GaN on the InAlGaN at a temperature of 800 to 900° C.

6. The process according to claim 5,
wherein the step of growing the another GaN includes a step of growing the another GaN layer by a thickness of 3 nm.

7. The process according to claim 1,
further including a step of growing an aluminum nitride (AlN) after the step of growing the GaN but before the step of growing the InAlGaN.

8. The process according to claim 1,
wherein the step of growing the InAlGaN is carried out using hydrogen (H) as a carrier gas.

9. The process according to claim 1,
wherein the step of growing the InAlGaN grows the InAlGaN to be substantially lattice matched with an AlGaN.

10. The process according to claim 1,
wherein the step of growing the InAlGaN grows the InAlGaN by a thickness of 9 nm.
